(19) United States
(12) Patent Application Publication
(10) Pub. No.: US 2016/0180924 A1
(43) Pub. Date: Jun. 23, 2016

(54) METHOD AND APPARATUS FOR REDUCING LEAKAGE CURRENT IN MEMORY

(71) Applicants: Paramjeet Singh, Delhi (IN); Manmohan Rana, Ghaziabad (IN)

(72) Inventors: Paramjeet Singh, Delhi (IN); Manmohan Rana, Ghaziabad (IN)

(21) Appl. No.: 14/580,171

(22) Filed: Dec. 22, 2014

(51) Int. Cl. G11C 11/418

(52) U.S. Cl. CPC G11C 11/418

(57) ABSTRACT

A method and apparatus in which word line drivers associated with memory word lines are selectively powered based on an active memory address reduces current consumption in a memory.

### BACKGROUND OF THE INVENTION

The present invention relates generally to semiconductor memory devices and, more particularly to reducing power consumption in such memories.

In order to reduce power consumption in memory devices it is common for peripheral circuitry, such as row decoders and column decoders, to include power switches that are used to reduce a leakage current in a low power mode. In the low power mode the power switches are used to power off the peripheral circuitry.

However, in an operational mode, the peripheral circuitry is powered on and current is consumed. The leakage current in row decoders is a significant percentage of the total current consumption of the memory device. Depending upon parameters of the memory, such as the number of words and word length, the leakage current of a row decoder may be up to 80% of the total current consumption of a memory device. Accordingly, it would be advantageous to be able to reduce the leakage current in a memory device.

### BRIEF DESCRIPTION OF THE DRAWINGS

The invention, together with objects and advantages thereof, may best be understood by reference to the following description of preferred embodiments together with the accompanying drawings in which:

FIG. 1 is a schematic diagram of a row decoder cell of a memory according to an embodiment of the invention;

FIG. 2 is a is a schematic diagram of a row decoder cell of a memory according to another embodiment of the invention;

FIG. 3 is a schematic diagram of a row decoder cell of a memory according to a further embodiment of the invention; and

FIG. 4 is a flow chart of a method of reducing leakage current in a memory device according to an embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides for a method of reducing leakage current of a memory device in an operational mode by selectively powering one or more word line driver circuits within the memory responsive to an addressed memory cell.

In another embodiment, the present invention provides for a memory comprising a plurality of row decoders each comprising one or more power switches arranged to control power to one or more word line drivers and circuitry arranged to selectively operate the one or more power switches responsive to an at least partially decoded address.

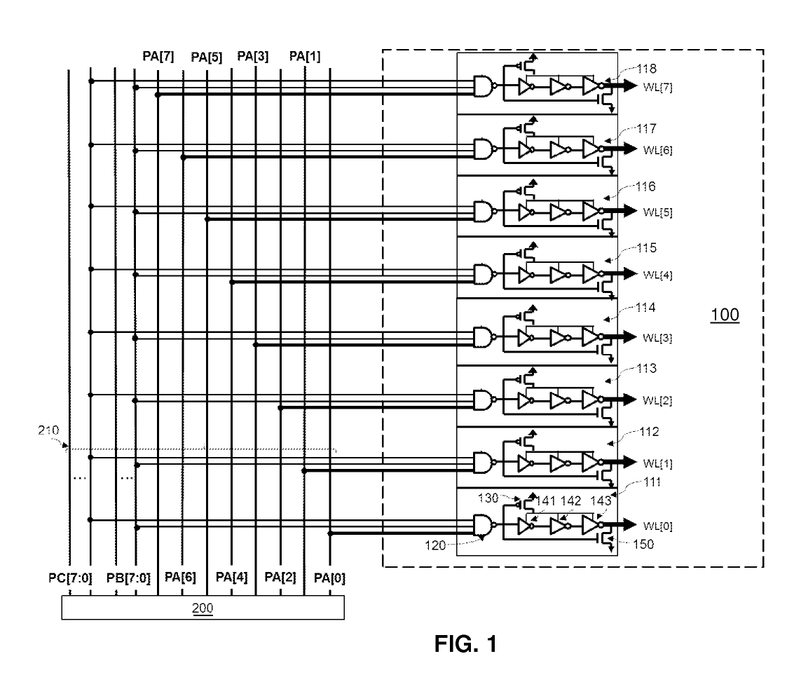

Referring now to FIG. 1, a row decoder cell 100 of a memory, such as an SRAM memory, in accordance with an embodiment of the present invention, is shown. The row decoder cell 100 is a unit of the memory comprising circuitry for selectively activating one of a plurality of word lines of the memory responsive to an at least partially decoded address. As will be appreciated, activation of a word line is used to select a memory cell for access. The memory comprises a plurality, potentially hundreds, of row decoder cells, as will be appreciated. The row decoder cell 100 illustrated in FIG. 1 is arranged to control eight word lines WL[0], WL[1], . . . WL[7], although it will be realized that the cell 100 may control other numbers of word lines. It will also be realized that the memory may comprise row decoders which are not arranged in cells.

The row decoder cell 100 comprises a plurality of word line driver circuits 111, 112, . . . 118. Each word line driver circuit 111, 112, . . . 118 is arranged to selectively activate a corresponding word line of the memory. Each word line driver circuit 111, 112, . . . 118 comprises circuitry arranged to determine when an address corresponding to the respective word line is activated and to control a power switch to apply power to one or more word line drivers responsive thereto. In this way, the word line drivers are only powered in an operational mode of the memory responsive to the address corresponding to the respective word line. A leakage current of the row decoder cell 100 may therefore be reduced since, even in an operational state of the memory, word line drivers are not powered until an address corresponding to a word line is placed on at least one bus coupled to the word line driver.

Description will now be made of the word line driver circuit 111, although it will be realised that all of the word line driver circuits 111, 112, . . . 118 may comprise equal components. The word line driver circuit 111 comprises addressing circuitry 120, a power switch 130 which is operable by the addressing circuitry 120, and one or more word line drivers 141, 142, 143 which are powered, i.e. provided with operating current, via the power switch 130. In particular the power switch 130 is arranged to control a positive voltage (Vdd) supplied to the one or more word line drivers 141, 142, 143. It will be realised that the word line driver circuit 111 may comprise more than one power switch controlled by the addressing circuitry. In some embodiments, the word line driver circuit 111 comprises a word line grounding switch 150 which is arranged to selectively connect the respective word line WL[0] to ground, as will be explained.

The addressing circuitry 120 is connected to a plurality of pre-decode address lines 210 output from an address pre-decoder 200. The address pre-decoder 200 is arranged to perform a pre-decode operation on data received via a memory address bus (not shown) to which the pre-decoder 200 is connected, and to output a partially decoded address onto the plurality of pre-decode address lines 210. In the embodiment shown in FIG. 1 the pre-decode address lines 210 comprise three pre-decode buses which each comprise eight address lines PA[0:7], PB[0:7], PC[0:8], although it will be realised that other numbers of pre-decode buses and address lines may be used. It will also be realised that other arrangements of address decoding may be used. In FIG. 1, the pre-decoder 200 is arranged to selectively activate one address line of each the pre-decode buses PA[0:7], PB[0:7], PC[0:8] when a selected memory address is within an address range of the pre-decoder 200. The pre-decode address lines 210 may be gated with a chip select (CS) line and a system clock signal such that the pre-decode address lines 210 are only active when the CS line corresponding to the memory and clock signal are logic 1 (high). In this way, all power switches 130 of a non-enabled memory device are turned off, thereby reducing leakage current associated with the memory.

The addressing circuitry 120 is arranged to operate responsive to the plurality of pre-decode address lines 210, in particular responsive to the partially decoded address placed thereon in operation by the pre-decoder 200. In one embodiment the addressing circuitry 120 comprises a NAND gate having a plurality of inputs connected to the pre-decode address lines 210. In one embodiment the NAND gate has one input connected to each of the pre-decode buses PA, PB, PC. Each input of the NAND gate is connected to one line of each of the pre-decode buses PA, PB, PC, as illustrated in FIG. 1. As shown, each of the word line driver circuits 111, 112, . . . 118 in FIG. 1 has an input of the respective NAND gate connected to a different line of one of the pre-decode buses, such as the bus PA. Connections to the other two pre-decode buses PB, PC may be the same for the word line driver circuits 111, 112, . . . 118 illustrated in FIG. 1. In this way each NAND gate 120 is responsive to a respective partially decoded address on the pre-decode buses 210. As will be appreciated, each NAND gate outputs a logic 0 responsive to all inputs being logic 1 when the corresponding address is selected.

The power switch 130 is operable responsive to an output of the addressing circuitry 120. In the embodiment shown in FIG. 1, the power switch 130 is arranged to receive an output of the addressing circuitry 120. In one embodiment the power switch 130 is a MOS transistor. The output of the addressing circuitry is received at a gate input of the MOS transistor. The MOS transistor may be a PMOS device which is operative in response to a logic 0 output by the NAND gate 120 to selectively supply power to the word line drivers 141, 142, 143. Therefore it will be appreciated that the power switch 130 is activated only when a corresponding address is placed on the pre-decode address lines 210. The power switch 130 is arranged to control the positive supply voltage Vdd to the word line drivers 141, 142, 143.

The word line drivers 141, 142, 143 are arranged in the embodiment shown in FIG. 1 in series. The word line drivers 141, 142, 143 may comprise a first word line driver 141 and a second word line driver 143 for driving a long word line provided to a cell of the memory. As shown in FIG. 1, embodiments of the invention may comprise more than two, such as three, word line drivers 141, 142, 143 arranged in series to drive the corresponding word line. Each word line driver 141, 142, 143 may be increasingly larger in size to provide increasing current to the respective word line such as word line WL[0]. As noted above, the power switch 130 is arranged to selectively provide the supply voltage to the word line drivers 141, 142, 143 responsive to a selected memory address. In this way, the leakage current of peripheral circuitry associated with the memory is reduced when the memory is operational, since the word line drivers 141, 142, 143 are not powered or provided with the supply voltage until the corresponding memory address is selected. It will be understood that the operational state of the memory is when data may be accessed, such as to be written or read to/from the memory.

As further illustrated in FIG. 1, the illustrated embodiment of word line driver circuit 111 comprises the word line grounding switch 150, which is arranged to selectively connect the word line WL[0] provided to the memory to ground when the one or more word line drivers 141, 142, 143 are not powered. The word line grounding switch 150 may be connected between an output of a last word line driver 143 and ground. The word line grounding switch 150 may be an MOS transistor of an opposite type to the power switch 130. An input to the word line grounding switch 150 may also be provided from the addressing circuitry 120. When the word line grounding switch 150 is an MOS transistor of an opposite type to the power switch 130, a connection between switching inputs is made responsive to an opposite logic input than for the power switch 130. In particular the word line grounding switch 150 may be an NMOS transistor where a connection between source and drain switching inputs is made responsive to a logic 1 output from the NAND gate 120 thereby causing the word line to be connected to ground when the corresponding address is not present on the pre-decode address lines 210. That is, the one or more word line drivers 141, 142, 143 for the word line WL[0] are selectively powered in an interlocking relationship with the word line being connected to ground. In said interlocking relationship when the word line drivers 141, 142, 143 are powered the corresponding word line WL[0] is disconnected from ground and when the word line drivers 141, 142, 143 are not powered the corresponding word line is connected to ground.

Advantageously the selective connection of the word line WL[0] to ground prevents floating of the word line WL[0] when the one or more word line drivers 141, 142, 143 are not powered. The connection to ground ensures that the corresponding memory cell is not accidentally selected when the word line drivers 141, 142, 143 are not powered.

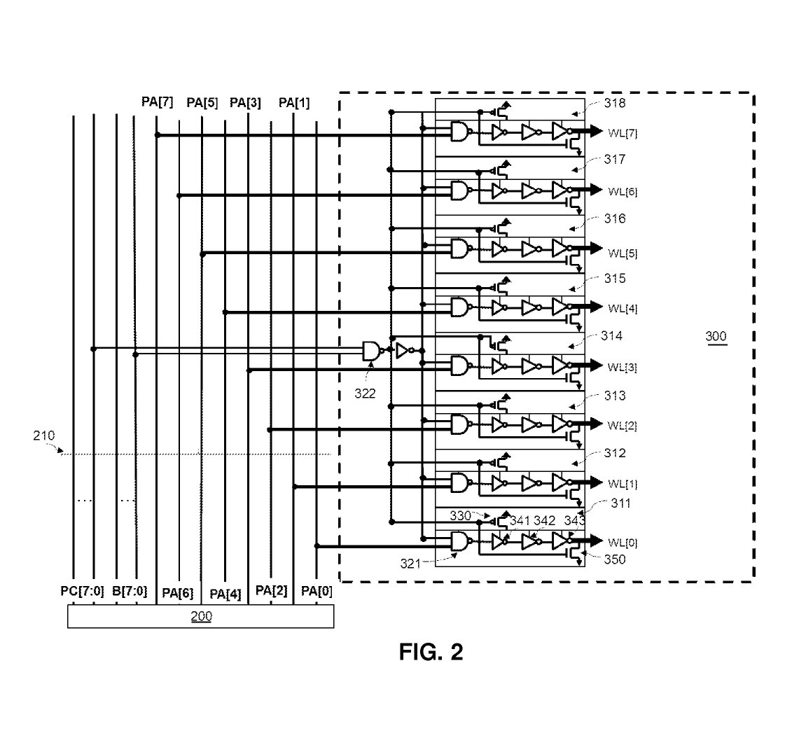

Referring to FIG. 2, a row decoder cell 300 according to another embodiment of the present invention is illustrated. As in FIG. 1, the row decoder cell 300 comprises a plurality of word line driver circuits 311, 312, . . . 318 each associated with a respective word line of the memory. Each word line driver circuit 311, 312, . . . 318 comprises addressing circuitry 321, 322, a power switch 330, and one or more word line drivers 341, 342, 343. In some embodiments each word line driver circuit 311, 312, . . . 318 comprises a word line grounding switch 350. Unless otherwise stated the row decoder cell 300 is as described with reference to FIG. 1.

Referring specifically to word line driver circuit 311, although it will be realised that the other word line driver circuits 312-318 have identical structure, the addressing circuitry 321, 322 comprises a first portion 321 uniquely associated with the respective word line driver circuit 311 and a second portion 322 which is shared between a plurality of word line driver circuits 311, 312, . . . 318 of the row decoder cell 300. In the embodiment shown in FIG. 2, the first portion 321 is arranged to provide a logic input to the one or more word line drivers 341, 342, 343 whilst the second portion 322 is arranged to control a power supply to the one or more word line drivers 341, 342, 343. It will be appreciated that the second portion 322 also contributes to the logic input of the word line drivers 341, 342, 343 by providing an input to the first portion 321. Thus to activate a respective word line, such as word line WL[0], both the first and second portions 321, 322 of the addressing circuitry is required to be activated. The first and second portions 321, 322 of the addressing circuitry are connected to respective portions of the address lines 210.

In the embodiment illustrated in FIG. 2, the first portion 321 of each addressing circuit is responsive to a first portion of the pre-decode address lines 210. In particular, the first portion 321 of each addressing circuit 320 is connected to a respective line of one of the pre-decode buses 210, such as PA. The second portion 322 of each addressing circuit 320 is responsive to a second portion of the pre-decode address lines 210. In particular, the second portion 322 may be connected to a respective line of each of the remaining pre-decode buses, such as two pre-decode buses PB, PC. In this way, the second portion 322 of the addressing circuit is responsive to a combination of a portion of the pre-decode address lines 210 to provide an output to the plurality of word line driver circuits 311, 312, . . . 318 of the cell 300, and the first portion 321 of the addressing circuit is responsive to another portion the pre-decode address lines 210 to provide the logic input to the one or more word line drivers 341, 342, 343 of the respective one of the word line driver circuits 311, 312, . . . 318.

The first portion 321 comprises, in one embodiment, a first NAND gate arranged to receive a first input from a respective one of the first portion of the pre-decode address lines 210. The first NAND gate may have a first input connected to one of the address lines of the pre-decode bus, such PA. A second input of the first NAND gate 321 is provided from the second portion 322 of the addressing circuit. The second portion 322 may comprise a second NAND gate arranged to receive inputs from the respective second portion of the pre-decode address lines 210. The second NAND gate may receive an input from each of the two pre-decode buses, PB, PC. The output of the second NAND gate is provided to the power switch 330. The output of the second NAND gate is provided via an inverter as an input to the first NAND gate of the first portion 321 of the addressing circuit. It will be realised that inversion of the output of the second NAND is required to provide a logic 1 input to the first NAND when the address is placed on the second portion of the pre-decode address lines 210. The output of the second NAND gate may be further provided to the word line grounding switch 330.

In operation, when the inputs to the second NAND gate of the second portion 322 are logic 1, the second NAND gate outputs logic 0, thereby causing the power switch 330 to provide the supply voltage Vdd to the one or more word line drivers 341, 342, 343 and the word line WL[0] to be disconnected from ground in embodiments having the word line grounding switch 350. Furthermore one of the inputs to the first NAND gate of the first portion 321 is at logic 1 and the first NAND gate is responsive to activation of the corresponding line of the pre-decode bus PA.

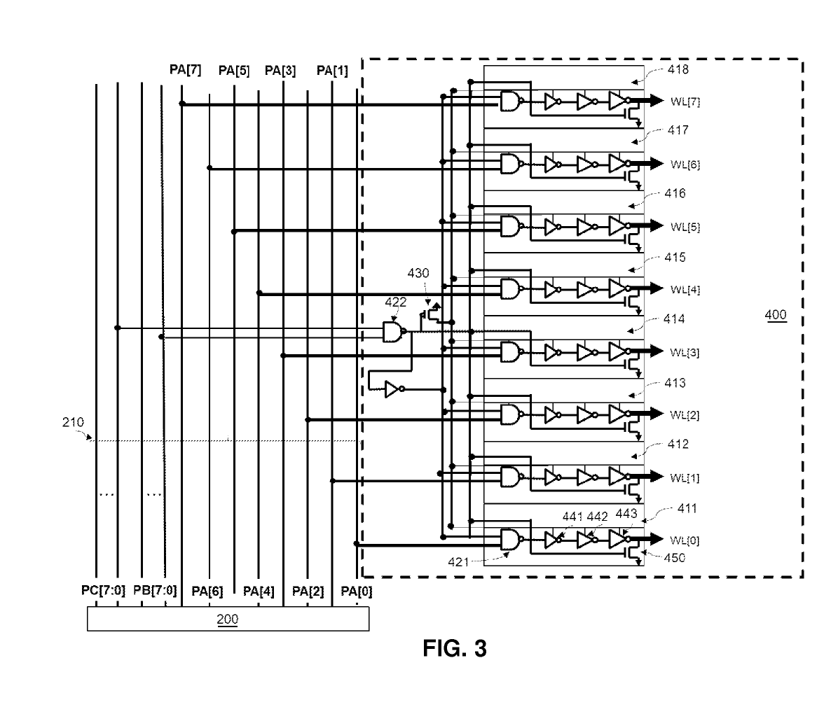

FIG. 3 illustrates a row decoder cell 400 according to a further embodiment of the present invention. In the row decoder cell 400 a power switch 430 is controlled to selectively provide power to one or more word line drivers 341, 342, 343 of a plurality of word lines. In particular a supply voltage to word line drivers 341, 342, 343 for the plurality of word lines WL[0:8] is simultaneously controlled.

The row decoder cell 400 comprises a plurality of word line driver circuits 411, 412, . . . 418 each associated with a respective word line of a memory. Each word line driver circuit 411, 412, . . . 418 comprises addressing circuitry 421, 422. As in the embodiment shown in FIG. 2, the addressing circuitry 421,422 of the row decoder cell 400 comprises a first portion 421 uniquely associated with each respective word line driver circuit 411 and a second portion 422 which is shared between a plurality of word line driver circuits 411, 412, . . . 418. The addressing circuitry 421, 422 is responsive to a pre-decode address bus 420 output from an address pre-decoder 400. A power switch 430 is also shared between the plurality of word line driver circuits 411, 412, . . . 418 for controlling power to word line drivers of the plurality of word line driver circuits 411, 412, . . . 418. That is, the power switch 430 simultaneously switches a supply voltage to word line driver circuits 411, 412, . . . 418 corresponding to a plurality of word lines of the memory.

The first portion 421 of the addressing circuitry is connected to a first portion of the pre-decode address lines 210 such as a respective line of one of the pre-decode buses, such as PA. The second portion 422 of the addressing circuitry is responsive to a second portion of the pre-decode address lines 210. As in FIG. 2, the first and second portions 421, 422 may each comprise a NAND gate. In particular, the second portion 422 of the addressing circuit may be connected to a respective line of each of the remaining pre-decode buses, such as two pre-decode buses PB, PC. The power switch 430 is controlled responsive to an output of the second portion 422. When an address corresponding to one of the plurality of word line driver circuits 411, 412, . . . 418 of the row decoder cell 400 is placed on pre-decode address lines 420, the second portion 422 outputs a signal to control the power switch 430 to selectively provide an operating voltage to the one or more word line drivers 441, 442, 443 of the plurality of word line driver circuits 411, 412, . . . 415 of the row decoder cell 400. The output from the second portion 422 of the addressing circuit is provided to an inverter to provide an input to the first portion 421 of the addressing circuitry. A logic input to each of the word line drivers 441, 442, 443 is controlled by the first portion 421 of the addressing circuitry. The output of the second portion 422 is combined with the first portion of the pre-decode address lines 210. In particular a respective line of one of the pre-decode buses is provided as an input to a NAND gate of the first portion 421 with the inverted output of the NAND gate of the second portion 422. Each of the word line driver circuits 411, 412, . . . 418 may comprise a word line grounding switch 450 for selectively connecting the plurality of word lines to ground. In particular the word lines output from the row decoder cell may be selectively connected to ground in an interlocking relationship with the power switch 430 control.

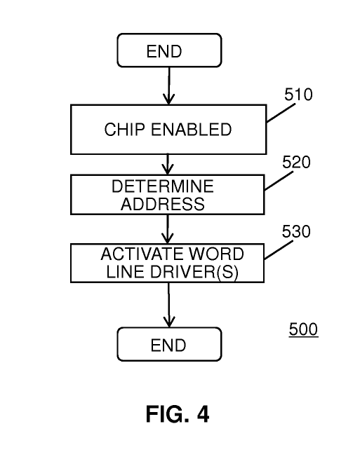

FIG. 4 is a flow chart illustrating a method 500 according to an embodiment of the present invention. The method reduces leakage current associated with a memory, such as an SRAM. The method 500 also reduces leakage current in peripheral circuitry associated with the memory. The method 500 may be performed by row decoders associated with the memory. At a start of the method 500 the memory is operational, i.e., not in a sleep-state or low power state.

The method 500 comprises a step 510 in which a chip-enable signal is provided to the memory, thus enabling access to the memory cells. However until a memory cell is addressed the power switches 130, 330, 430 to the word line drivers remain off. That is, an operating voltage is not provided to the word line drivers, thereby reducing a leakage current associated with the memory in the operational state.

In step 520 an address is placed on an address bus associated with the memory to access a memory cell. The memory cell may be accessed to read data from or write data to the memory cell. A word line corresponding to the address is determined in step 520. Step 520 may comprise the address being pre-decoded and selected lines of one or more pre-decode address busses being activated. The word line may be determined by addressing circuitry 120, 321, 322, 421, 422 as previously described, which may be responsive to the one or more pre-decode address busses.

In step 530 one or more word line drivers 141, 142, 341, 342, 343 associated with the word line corresponding to the address are activated. That is, only the one or more word line drivers 141, 142, 341, 342, 343 corresponding to the address are provided with an operating voltage in step 530. Other word line drivers associated with different word lines remain inoperative, thus reducing the leakage current associated with the memory. The powered word line drivers 141, 142, 341, 342, 343 provide an active signal on the corresponding word line, where the active signal may be a logic 1 to access the addressed memory cell. Step 530 may comprise disconnecting the word line from ground prior to the active signal being placed on the word line.

Advantageously, the present invention provides a method of reducing power consumption associated with a memory, in particular reducing leakage current associated with the memory whilst in an operational mode. In embodiments of the present invention, only word line drivers corresponding to an accessed word line are provided with an operating voltage, such that word line drivers associated with other, un-accessed, word lines do not leak current.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A method of reducing leakage current in an operational mode of a memory device, comprising:
decoding a memory address within a memory;
selectively powering one or more word line drivers within the memory that are associated with a word line corresponding to the memory address.

2. The method of claim 1, further comprising selectively connecting to ground one or more word lines based on the memory address.

3. The method of claim 2, wherein the one or more word line drivers are selectively powered in an interlocking relationship with the one or more word lines being connected to ground.

4-5. (canceled)

6. The method of claim 1, wherein the decoding comprises:
pre-decoding the memory address and outputting a decoded memory address onto one or more pre-decoded address lines;
determining whether the decoded memory address corresponds to a predetermined address and, if so, selectively powering the one or more word line drivers in response thereto.

7. The method of claim 6, further comprising: providing an input to a word line driver in response thereto.

8. The method of claim 1, wherein the selectively powering comprises controlling a power switch in response to the memory address.

9. The method of claim 8, wherein the power switch switches a voltage supply provided to the at least one word line driver.

10. The method of claim 1, further comprising accessing a memory cell corresponding to the word line associated with the one or more word line drivers for a read or write operation.

11. The method of claim 1, wherein in the operational mode of the memory device is powered to allow read or write access.

12. A row decoder for a memory, comprising:
a plurality of word lines;
one or more word line drivers associated with each of the plurality of word lines;
at least one switching device that controls a supply voltage to the one or more word line drivers;
addressing circuitry arranged to determine a decoded address on an address bus and to control the at least one switching device to selectively power the one or more word line drivers that are associated with a word line corresponding to the decoded address.

13. The row decoder of claim 12, wherein the at least one switching device comprises a plurality of switching devices, each associated with a respective one of the plurality of word lines, and wherein each controls the supply voltage to the one or more word line drivers associated with the corresponding word line.

14. The row decoder of claim 13, wherein the addressing circuitry is arranged to determine one of the plurality of word lines corresponding to the decoded address, and to control the respective switching device to provide the supply voltage to the one or more word line drivers associated with the word line.

15. (canceled)

16. The row decoder of claim 12, further comprising:
a plurality of word line switching devices associated with the plurality of word lines, wherein each word line switching device selectively connects a respective one of the word lines to ground.

17. The row decoder of claim 16, wherein the word line switching devices are controlled in an interlocking relationship with the at least one switching device that controls the supply voltage to the one or more word line drivers associated with the respective word line.

18. A memory system, comprising:
an array of SRAM memory cells arranged in a plurality of rows and a plurality of columns, each of the plurality of rows having a corresponding word line;
a row decoder comprising at least one word line driver associated with each word line;
an address pre-decoder arranged to pre-decode addresses on an address bus and to selectively activate pre-decoded address lines in response thereto; and
addressing circuitry coupled to the pre-decoded address lines and arranged to control one or more power switches, each of the power switches arranged to selectively provide power to the at least one word line driver associated with a word line associated with the pre-decoded address lines.

19. The memory system of claim 18, wherein the addressing circuitry comprises a plurality of gates coupled to the address bus each arranged to provide an input to a word line driver associated with a respective one of the word lines.
